(19) United States
(12) Patent Application Publication
(10) Pub. No.: US 2015/0291439 A1
(43) Pub. Date: Oct. 15, 2015

(54) METHOD FOR PRODUCING CUPROUS OXIDE FINE PARTICLES, CUPROUS OXIDE FINE PARTICLES AND METHOD OF PRODUCING CONDUCTOR FILM

(71) Applicants: Akihiro Kinoshita, Fujimino-city (JP); Naohito Uemura, Fujimino-city (JP)

(72) Inventors: Akihiro Kinoshita, Fujimino-city (JP); Naohito Uemura, Fujimino-city (JP)

(73) Assignee: NISSHIN ENGINEERING INC., Tokyo (JP)

(21) Appl. No.: 14/394,708

(22) PCT Filed: Mar. 31, 2014
(86) PCT No.: PCT/JP2014/059577

§ 371 Date: Oct. 15, 2014

(30) Foreign Application Priority Data
Jun. 21, 2013 (JP) 2013-130524

(51) Int. Cl. C01G 3/02; H05K 3/00

(52) U.S. Cl. CPC C01G 3/02; H05K 3/0091; C01P 2004/64; C01P 2002/60; H05K 2203/1105

(57) ABSTRACT

A cuprous oxide fine particle production method includes a production step of producing cuprous oxide fine particles using copper compound powder and a thermal plasma flame. The thermal plasma flame is derived from an inert gas. The production step includes a step of supplying into the thermal plasma flame, the copper compound powder dispersed using a carrier gas or slurry obtained by dispersing the copper compound powder in water in the form of droplets. The production step preferably further includes a step of supplying a cooling gas to an end portion of the thermal plasma flame.

### TECHNICAL FIELD

The present invention relates to a method of producing cuprous oxide (Cu₂O) fine particles using a thermal plasma flame and the cuprous oxide fine particles as well as a method of producing a conductor film. The present invention more specifically relates to a method of producing cuprous oxide fine particles and the cuprous oxide fine particles as well as a method of producing a conductor film which are applicable to preservatives for use in ship bottom paints (antifouling paints), germicides, pesticides, catalysts, various devices such as solar cells and light-emitting devices, conductive pastes, electrodes in electronic components such as multilayer ceramic capacitors, wiring of printed circuit boards, wiring of touch panels, flexible electronic paper and the like.

### BACKGROUND ART

At present, various types of fine particles are used in various applications. For instance, fine particles such as metal fine particles, oxide fine particles, nitride fine particles and carbide fine particles have been used in the production of sintered bodies for use as electrical insulation materials for semiconductor substrates, printed circuit boards, various electrical insulation parts and the like, materials for high-hardness and high-precision machining tools such as cutting tools, dies and bearings, functional materials for grain boundary capacitors, humidity sensors and the like, and precision sinter molding materials, and in the production of thermal sprayed parts such as engine valves made of materials that are required to be wear-resistant at a high temperature, as well as in the fields of electrode or electrolyte materials and various catalysts for fuel cells.

It is known that, of those fine particles, cuprous oxide fine particles can be formed by a solid-phase process, a liquid-phase process and a gas-phase process. Methods of producing cuprous oxide particles are specifically disclosed in, for example, Patent Literatures 1 and 2.

Patent Literature 1 discloses a method of producing cuprous oxide powder which involves adding an alkali solution and a reducing agent solution to an aqueous solution containing divalent copper ions to reductively deposit cuprous oxide fine particles, wherein the cuprous oxide powder having a 50% particle size of 0.05 to 1.0 μm, a carbon content of up to 0.1 wt % and a chlorine content of less than 0.01 wt %, and having a shape in which a spherical shape, a substantially spherical shape and at least one of a hexahedral shape and a scale-like shape are mixed is produced by using a carbon and chlorine-free alkali solution as the alkali solution and also using a carbon and chlorine-free reducing agent solution as the reducing agent solution.

Patent Literature 1 uses, as the carbon and chlorine-free reducing agent, at least one reducing agent selected from the group consisting of hydroxylamine sulfate, hydroxylamine nitrate, sodium sulfite, sodium hydrogen sulfite, sodium dithionite, hydrazine sulfate, hydrazine phosphate, hydrazine, hypophosphorous acid and sodium hypophosphite.

In Patent Literature 2, a copper material solution is prepared by adding, for example, copper (I) acetate used as a copper compound containing monovalent copper to a specific amine such as benzylamine or N-propylamine and dissolving the resulting mixture in a solvent such as ethanol, 2-methoxyethanol, methanol or benzyl alcohol. Then, the copper material solution is hydrolyzed in a W/O microemulsion solution containing a surfactant and water dispersed in a hydrophobic solvent, for example, cyclohexane or benzene, thereby producing Cu₂O nanoparticles. In Patent Literature 2, high-purity Cu₂O nanoparticles having an average particle size of up to 10 nm and exhibiting good dispersibility are obtained without the need for a reducing agent.

### CITATION LIST

### Patent Literature

Patent Literature 1: JP 2010-59001 A

Patent Literature 2: JP 2011-1213 A

### SUMMARY OF INVENTION

### Technical Problems

In Patent Literature 1, an alkali solution and a reducing agent solution such as hydroxylamine sulfate are added to an aqueous solution containing divalent copper ions. This technique has problems in that the reducing agent is difficult to adjust and remains as an impurity of cuprous oxide powder.

Patent Literature 2 uses an alkoxide material containing monovalent copper and this technique has a problem of increased cost.

Furthermore, both of Patent Literatures 1 and 2 involve a synthesis in a liquid phase and hence the solvent that can be used is limited, and there is also a problem in that a cumbersome treatment such as solvent displacement may often be necessary when prepared fine particles are used.

An object of the present invention is to solve the problems inherent in the prior art and to provide a cuprous oxide fine particle production method capable of easily and reliably producing cuprous oxide fine particles and the resulting cuprous oxide fine particles as well as a method of producing a conductor film.

### Solution to Problems

In order to achieve the above object, the present invention provides a cuprous oxide fine particle production method comprising: a production step of producing cuprous oxide fine particles using copper compound powder and a thermal plasma flame, wherein the thermal plasma flame is derived from an inert gas.

The production step preferably comprises a step of dispersing the copper compound powder using a carrier gas to supply the copper compound powder into the thermal plasma flame.

The production step preferably comprises: a step of dispersing the copper compound powder in water to obtain a slurry; and a step of converting the slurry into droplets to supply the droplets into the thermal plasma flame.

The copper compound powder is, for example, cupric oxide powder.

The production step preferably further comprises a step of supplying a cooling gas to an end portion of the thermal plasma flame.

For example, the inert gas is at least one selected from helium gas, argon gas and nitrogen gas.

The present invention also provides cuprous oxide fine particles having a particle size of 1 to 100 nm and satisfying 0.5 Dp≦Dc≦0.8 Dp where the particle size is denoted by Dp and a crystallite diameter is denoted by Dc.

The present invention further provides a conductor film production method comprising:

a step of dispersing cuprous oxide fine particles having a particle size of 1 to 100 nm and satisfying 0.5 Dp≦Dc≦0.8 Dp where the particle size is denoted by Dp and a crystallite diameter is denoted by Dc in a solvent to obtain a dispersion; a step of applying the dispersion onto a substrate and drying the applied dispersion to form a coating film; and a step of heating the coating film in a reducing atmosphere for a predetermined period of time to obtain a conductor film.

The conductor film is preferably formed in a wiring pattern shape. For example, the conductor film can be used in at least one of at least a printed circuit board, a touch panel and a flexible board. The conductor film can be used in an internal electrode or an external electrode of an electronic component.

### Advantageous Effects of Invention

The present invention is capable of easily and reliably producing cuprous oxide fine particles.

The present invention is also capable of reliably producing a copper conductor film using the cuprous oxide fine particles.

### BRIEF DESCRIPTION OF DRAWINGS

FIG. 1 is a schematic view showing an apparatus for producing fine particles that may be used in a method of producing cuprous oxide fine particles according to an embodiment of the invention.

FIG. 2A is a graph showing analysis results according to X-ray diffractometry of particles obtained by treating cupric oxide powder using nitrogen gas as a plasma gas and nitrogen gas as a cooling gas; and FIG. 2B is a graph showing analysis results according to X-ray diffractometry of particles obtained by treating cupric oxide powder using oxygen gas as a plasma gas and nitrogen gas as a cooling gas.

FIG. 3A is a graph showing analysis results according to X-ray diffractometry of particles obtained by treating cupric oxide powder using oxygen gas as a plasma gas and air as a cooling gas; and FIG. 3B is a graph showing analysis results according to X-ray diffractometry of particles obtained by treating cupric oxide powder using oxygen gas as a plasma gas and nitrogen gas as a cooling gas.

FIG. 4A is a graph showing analysis results according to X-ray diffractometry of cuprous oxide fine particles produced using a cooling gas; and FIG. 4B is a graph showing analysis results according to X-ray diffractometry of cuprous oxide fine particles produced without using a cooling gas.

FIGS. 5A and 5B are micrographs substituted for drawings corresponding to the cuprous oxide fine particles shown in FIGS. 4A and 4B, respectively.

FIG. 6 is a graph showing weight variations of Sample Nos. 1 to 4.

FIG. 7 is a graph showing analysis results according to X-ray diffractometry of particles in Sample No. 4 prior to thermal treatment, and analysis results according to X-ray diffractometry of particles obtained by subjecting the particles in Sample No. 4 to thermal treatment at a temperature of 200° C. for 2 hours.

FIG. 8A is a micrograph substituted for a drawing showing the particles in Sample No. 4 prior to thermal treatment; and FIG. 8B is a micrograph substituted for a drawing showing the particles in Sample No. 4 after thermal treatment is performed at a temperature of 200° C. for 2 hours.

FIG. 9 is a flow chart illustrating a method of producing a conductor film using the cuprous oxide fine particles according to the invention.

### DESCRIPTION OF EMBODIMENTS

On the following pages, the method of producing cuprous oxide fine particles and the resulting cuprous oxide fine particles as well as the method of producing a conductor film according to the present invention are described in detail with reference to preferred embodiments shown in the accompanying drawings.

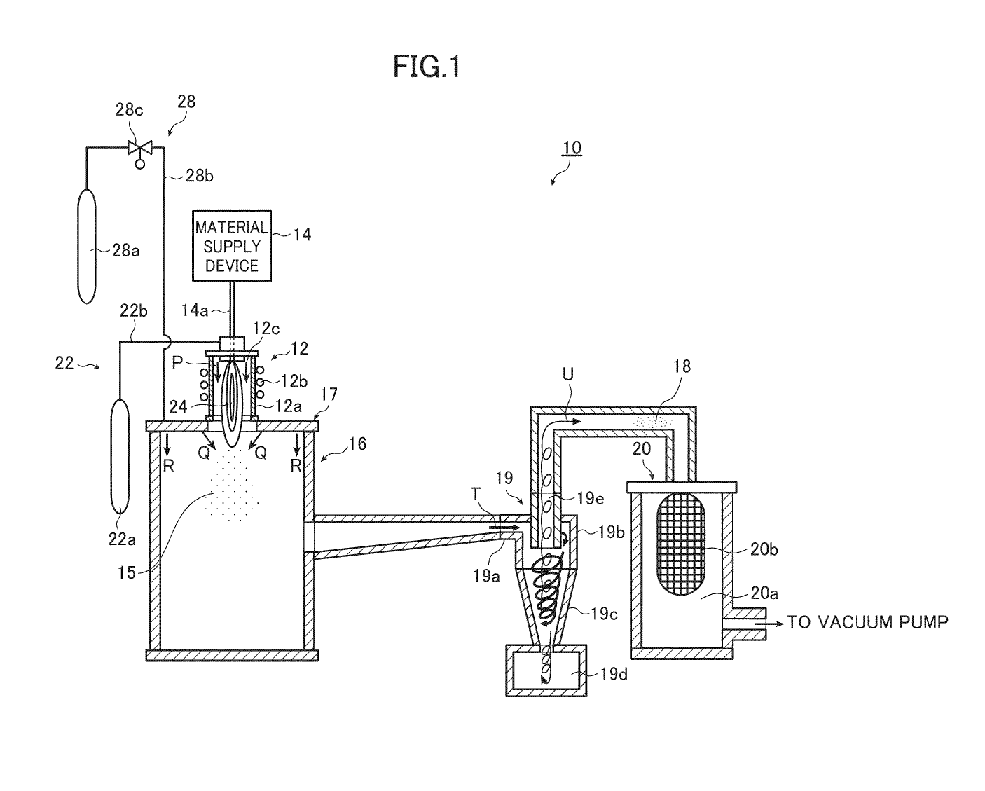

FIG. 1 is a schematic view showing an apparatus for producing fine particles that may be used in the method of producing cuprous oxide fine particles according to an embodiment of the invention.

A fine particle production apparatus 10 (hereinafter referred to simply as “production apparatus 10”) shown in FIG. 1 is used to produce fine particles of cuprous oxide (Cu₂O, copper (I) oxide).

The production apparatus 10 includes a plasma torch 12 generating thermal plasma, a material supply device 14 supplying a material for producing cuprous oxide fine particles (a powder material) into the plasma torch 12, a chamber 16 serving as a cooling tank for producing cuprous oxide primary fine particles 15, a cyclone 19 removing, from the produced primary fine particles 15, coarse particles having a particle size equal to or larger than an arbitrarily specified particle size, and a collecting section 20 collecting cuprous oxide secondary fine particles 18 having a desired particle size as obtained by classification in the cyclone 19.

Various devices in, for example, JP 2007-138287 A may be used for the material supply device 14, the chamber 16, the cyclone 19 and the collecting section 20.

In the embodiment under consideration, copper compound powder is used to produce cuprous oxide fine particles. The average particle size of the copper compound powder is appropriately set so as to readily evaporate in a thermal plasma flame and is, for example, up to 100 μm, preferably up to 10 μm and even more preferably up to 3 μm. Examples of the copper compound powder that may be used include cupric oxide (CuO) powder, cupric hydroxide (Cu(OH)₂) powder, cupric sulfate (CuSO₄) powder, cupric nitrate (Cu(NO₃)₂) powder and copper peroxide (Cu₂O₃, CuO₂, CuO₃) powder.

The plasma torch 12 includes a quartz tube 12a and a coil 12b for high frequency oscillation surrounding the outside of the quartz tube 12a. On top of the plasma torch 12, a supply tube 14a to be described later which is for supplying copper compound powder into the plasma torch 12 in the form of the copper compound powder or of a slurry containing the copper compound powder as will be described later is provided at the central portion thereof. A plasma gas supply port 12c is formed in the peripheral portion of the supply tube 14a (on the same circumference). The plasma gas supply port 12c is in a ring shape.

A plasma gas supply source 22 is configured to supply plasma gas into the plasma torch 12. The plasma gas supply source 22 has a gas supply section 22a, which is connected to the plasma gas supply port 12c through piping 22b. Although not shown, the gas supply section 22a is provided with a supply amount adjuster such as a valve for adjusting the supply amount.

Plasma gas is supplied from the plasma gas supply source 22 into the plasma torch 12 through the plasma gas supply port 12c. An inert gas is used as the plasma gas. For example, at least one gas selected from helium gas, argon gas and nitrogen gas is used as the inert gas.

For instance, at least one gas selected from, for example, helium gas, argon gas and nitrogen gas is stored in the gas supply section 22a. At least one gas selected from helium gas, argon gas and nitrogen gas is supplied as the plasma gas from the gas supply section 22a of the plasma gas supply source 22 into the plasma torch 12 in a direction indicated by an arrow P after having passed through the ring-shaped plasma gas supply port 12c via the piping 22b. Then, a high frequency voltage is applied to the coil 12b for high frequency oscillation to generate a thermal plasma flame 24 in the plasma torch 12.

Plasma gas should be at least one gas selected from helium gas, argon gas and nitrogen gas. The invention is not limited to a case where any of these gases is used alone but these may be used in combination.

It is necessary for the thermal plasma flame 24 to have a higher temperature than the boiling point of copper compound powder. On the other hand, the thermal plasma flame 24 preferably has a higher temperature because the copper compound powder is more easily converted into a gas phase state. However, there is no particular limitation on the temperature. For instance, the thermal plasma flame 24 may have a temperature of 6,000° C., and in theory, the temperature is deemed to reach around 10,000° C.

The ambient pressure inside the plasma torch 12 is preferably 1 atm or less. The ambient pressure of 1 atm or less is not particularly limited and is, for example, in a range of 0.5 to 100 kPa.

The outside of the quartz tube 12a is surrounded by a concentrically formed tube (not shown) and cooling water is circulated between this tube and the quartz tube 12a to cool the quartz tube 12a with the water, thereby preventing the quartz tube 12a from having an excessively high temperature due to the thermal plasma flame 24 generated in the plasma torch 12.

The material supply device 14 is connected to the upper portion of the plasma torch 12 through the supply tube 14a. For the material supply device 14, use may be made of, for example, two systems including one which supplies copper compound powder in the form of powder and the other which supplies copper compound powder in the form of slurry containing it.

For example, the device disclosed in JP 2007-138287 A may be used as the material supply device 14 which supplies copper compound powder in the form of powder. In this case, the material supply device 14 includes, for example, a storage tank (not shown) storing copper compound powder, a screw feeder (not shown) transporting the copper compound powder in a fixed amount, a dispersion section (not shown) dispersing the copper compound powder to convert it into the state of primary particles before the copper compound powder transported by the screw feeder is finally diffused, and a carrier gas supply source (not shown).

Together with a carrier gas from the carrier gas supply source to which a push-out pressure is applied, the copper compound powder is supplied into the thermal plasma flame 24 in the plasma torch 12 through the supply tube 14a.

The configuration of the material supply device 14 is not particularly limited as long as the device prevents the copper compound powder from agglomerating, thus making it possible to diffuse the copper compound powder in the plasma torch 12 with the dispersed state maintained. As with the above-described plasma gas, for example, an inert gas is used as the carrier gas. The flow rate of the carrier gas can be controlled with a float type flowmeter. The flow rate value of the carrier gas indicates a value on the scale of the flowmeter.

For example, the device disclosed in JP 2011-213524 A may be used as the material supply device 14 which supplies copper compound powder in the form of slurry. In this case, the material supply device 14 includes a vessel (not shown) for introducing slurry (not shown), an agitator (not shown) agitating the slurry in the vessel, a pump (not shown) for supplying the slurry into the plasma torch 12 through the supply tube 14a with a high pressure applied thereto, and an atomization gas supply source (not shown) which supplies atomization gas for supplying the slurry into the plasma torch 12 in the form of droplets. The atomization gas supply source corresponds to the carrier gas supply source. The atomization gas is also called carrier gas.

In a case where copper compound powder is supplied in the form of slurry in the embodiment under consideration, the copper compound powder is dispersed in water to obtain a slurry, which is used to produce cuprous oxide fine particles.

The mixing ratio between the copper compound powder and water in the slurry is not particularly limited and is, for example, 5:5 (50%:50%) in terms of weight ratio.

In a case where the material supply device 14 supplying copper compound powder in the form of slurry is used, atomization gas from the atomization gas supply source to which a push-out pressure is applied is supplied together with the slurry into the thermal plasma flame 24 in the plasma torch 12 through the supply tube 14a. The supply tube 14a has a two-fluid nozzle mechanism for spraying the slurry into the thermal plasma flame 24 in the plasma torch and converting it into droplets, whereby the slurry can be sprayed into the thermal plasma flame 24 in the plasma torch 12, in other words, the slurry can be converted into droplets. As with the carrier gas, for example, as with the above-described plasma gas, an inert gas is used for the atomization gas.

As described above, the two-fluid nozzle mechanism is capable of applying a high pressure to the slurry and atomizing the slurry with a gas, i.e., an atomization gas (carrier gas), and is used as a method for converting the slurry into droplets.

It should be noted that the nozzle mechanism is not limited to the above-described two-fluid nozzle mechanism but a single-fluid nozzle mechanism may also be used. Other exemplary methods include a method which involves causing a slurry to fall at a constant speed onto a rotating disk so as to convert the slurry into droplets (to form droplets) by the centrifugal force, and a method which involves applying a high voltage to the surface of a slurry to convert the slurry into droplets (to generate droplets).

The chamber 16 is provided below and adjacent to the plasma torch 12. The copper compound powder supplied into the thermal plasma flame 24 in the plasma torch 12 is evaporated to be converted into a gas phase state and the copper compound such as cupric oxide is reduced to form cuprous oxide fine particles. Then, the fine particles are quenched by cooling gas in the chamber 16 to produce primary fine particles 15 (cuprous oxide fine particles). The chamber 16 also serves as a cooling tank.

As already mentioned, for the material supply device 14, use may be made of, for example, two systems including one which supplies copper compound powder in the form of powder and the other which supplies copper compound powder in the form of slurry containing it.

A gas supply device 28 includes a gas supply source 28a and piping 28b, and further includes a pressure application means (not shown), such as a compressor and a blower, which applies push-out pressure to cooling gas supplied into the chamber 16 which will be described later. The gas supply device 28 is also provided with a pressure control valve 28c which controls the amount of gas supplied from the gas supply source 28a.

The gas supply source 28a stores cooling gas. As with the above-described plasma gas, for example, an inert gas is used as the cooling gas. The gas supply source 28a stores, for example, nitrogen gas.

The gas supply device 28 supplies, for example, nitrogen gas as the cooling gas at a predetermined angle, for example, in a direction of an arrow Q toward a tail portion of the thermal plasma flame 24, that is, toward an end of the thermal plasma flame 24 (an end portion of the thermal plasma flame 24) on the opposite side from the plasma gas supply port 12c, and also supplies the cooling gas from above to below along a side wall of the chamber 16, that is, in a direction of an arrow R shown in FIG. 1. The flow rate of the cooling gas can be controlled with, for example, a float type flowmeter. The flow rate value of the cooling gas indicates a value on the scale of the flowmeter.

In addition to the effect of quenching the cuprous oxide fine particles produced in the chamber 16 to form the primary fine particles 15 as will be described later in detail, the cooling gas supplied from the gas supply device 28 has additional effects including contribution to the classification of the primary fine particles 15 in the cyclone 19.

As will be described later, the inventors of the invention also confirm that cuprous oxide fine particles on the order of nanometers can be produced without quenching with cooling gas. Accordingly, it is not necessarily indispensable to provide the gas supply device 28.

In the case of the material supply device 14 which supplies in the form of powder, the copper compound powder supplied from the material supply device 14 into the plasma torch 12 together with carrier gas is converted into a gas phase state in the thermal plasma flame 24. The copper compound powder is quenched by nitrogen gas supplied from the gas supply device 28 toward the thermal plasma flame 24 in the direction of the arrow Q and the primary fine particles 15 of cuprous oxide are produced. In this process, nitrogen gas supplied in the direction of the arrow R prevents the primary fine particles 15 from adhering to the inner wall of the chamber 16.

On the other hand, in the case of the material supply device 14 which supplies in the form of slurry, a slurry in the form of droplets which contains the copper compound powder is supplied from the material supply device 14 into the plasma torch 12 using atomization gas at a predetermined flow rate and the copper compound in the slurry is reduced by the thermal plasma flame 24 to produce cuprous oxide. The cuprous oxide formed from the copper compound powder is also quenched in the chamber 16 by cooling gas supplied toward the thermal plasma flame 24 in the direction of the arrow Q to produce the primary fine particles 15 of cuprous oxide. In this process, argon gas supplied in the direction of the arrow R prevents the primary fine particles 15 from adhering to the inner wall of the chamber 16. As shown in FIG. 1, the cyclone 19 for classifying the produced primary fine particles 15 into a desired particle size is provided on the lower lateral side of the chamber 16. The cyclone 19 includes an inlet tube 19a which supplies the primary fine particles 15 from the chamber 16, a cylindrical outer casing 19b connected to the inlet tube 19a and positioned in an upper portion of the cyclone 19, a truncated cone part 19c continuing downward from a lower portion of the outer casing 19b and having a gradually decreasing diameter, a coarse particle collecting chamber 19d connected to a lower side of the truncated cone part 19c for collecting coarse particles having a particle size equal to or larger than the above-mentioned desired particle size, and an inner tube 19e connected to the collecting section 20 to be described later in detail and projecting from the outer casing 19b.

A gas stream containing the primary fine particles 15 produced in the chamber 16 is blown into the cyclone 19 from the inlet tube 19a thereof along the inner peripheral wall of the outer casing 19b, and this gas stream flows in the direction from the inner peripheral wall of the outer casing 19b to the truncated cone part 19c as indicated by an arrow T in FIG. 1, thereby forming a downward swirling stream.

When the above-described downward swirling stream is inverted to form an upward stream, coarse particles cannot follow the upward stream due to the balance between the centrifugal force and drag but come down along the side surface of the truncated cone part 19c and are collected in the coarse particle collecting chamber 19d. Fine particles which were influenced by the drag more than the centrifugal force are discharged outside the system from the inner tube 19e along with the upward stream on the inner wall of the truncated cone part 19c.

The apparatus is configured such that a negative pressure (suction force) is generated by the collecting section 20 as will be described in detail below and applied through the inner tube 19e. The apparatus is also configured such that, under the negative pressure (suction force), the cuprous oxide fine particles separated from the above-mentioned swirling gas stream are attracted as indicated by an arrow U and sent to the collecting section 20 through the inner tube 19e.

On the extension of the inner tube 19e, which is an outlet for the gas stream in the cyclone 19, the collecting section 20 for collecting the secondary fine particles (cuprous oxide fine particles) 18 having a desired particle size on the order of nanometers is provided. The collecting section 20 includes a collecting chamber 20a, a filter 20b provided in the collecting chamber 20a, and a vacuum pump (not shown) connected through a pipe provided below inside the collecting chamber 20a. The fine particles delivered from the cyclone 19 are sucked by the vacuum pump (not shown) to be introduced into the collecting chamber 20a, and remain on the surface of the filter 20b and are then collected.

The method of producing cuprous oxide fine particles using the above-described production apparatus 10 and the cuprous oxide fine particles produced by the production method are described below.

In the embodiment under consideration, for example, two systems including one which supplies copper compound powder in the form of powder and the other which supplies copper compound powder in the form of slurry containing it may be used in supplying a material. Methods of producing cuprous oxide fine particles according to the respective material supply systems are now described.

First of all, in the case of supply in the form of powder, for example, copper compound powder having an average particle size of up to 5 μm is charged into the material supply device 14 as copper compound powder.

For example, nitrogen gas is used as the plasma gas and a high frequency voltage is applied to the coil 12b for high frequency oscillation to generate a thermal plasma flame 24 in the plasma torch 12.

Further, the nitrogen gas is supplied in the direction of the arrow Q from the gas supply device 28 to the tail portion of the thermal plasma flame 24, i.e., to the end portion of the thermal plasma flame 24. At that time, the nitrogen gas is also supplied in the direction of the arrow R.

Next, the copper compound powder is transported with a gas, for example, argon gas used as the carrier gas to be supplied into the thermal plasma flame 24 in the plasma torch 12 through the supply tube 14a. The copper compound powder is evaporated in the thermal plasma flame 24 to be converted into a gas phase state and the copper compound is reduced to form cuprous oxide fine particles. Then, the cuprous oxide fine particles are quenched by cooling gas (nitrogen gas) in the chamber 16, whereby the production of cupric oxide is also suppressed to produce primary fine particles 15 (cuprous oxide fine particles).

The primary fine particles 15 produced in the chamber 16 are blown from the inlet tube 19a of the cyclone 19 together with a gas stream along the inner peripheral wall of the outer casing 19b, and this gas stream flows along the inner peripheral wall of the outer casing 19b as indicated by the arrow T in FIG. 1, thereby forming a swirling stream, which goes downward. When the above-described downward swirling stream is inverted to form an upward stream, coarse particles cannot follow the upward stream due to the balance between the centrifugal force and drag but come down along the side surface of the truncated cone part 19c and are collected in the coarse particle collecting chamber 19d. In addition, fine particles which were influenced by the drag more than the centrifugal force are discharged outside the system from the inner tube 19e together with the upward stream on the inner wall of the truncated cone part 19c.

Under the negative pressure (suction force) from the collecting section 20, the discharged secondary fine particles (cuprous oxide fine particles) 18 are attracted in the direction indicated by the arrow U in FIG. 1 and delivered to the collecting section 20 through the inner tube 19e to be collected on the filter 20b of the collecting section 20. The internal pressure of the cyclone 19 at that time is preferably 1 atm or less. In addition, an arbitrary particle size on the order of nanometers is defined according to the intended purpose for the particle size of the secondary fine particles (cuprous oxide fine particles) 18.

According to the embodiment under consideration, the cuprous oxide fine particles on the order of nanometers can be thus obtained easily and reliably by merely subjecting the copper compound powder to plasma treatment.

Moreover, the cuprous oxide fine particles can be easily reduced upon thermal treatment in a reducing atmosphere, thereby obtaining copper powder having electrical conductivity. Accordingly, the cuprous oxide fine particles can be used not only in the unreduced form but also as copper.

The cuprous oxide fine particles produced by the cuprous oxide fine particle production method according to the embodiment under consideration have a narrow particle size distribution, in other words, have a uniform particle size, and coarse particles having a particle size of 1 pm or more are hardly included. More specifically, the cuprous oxide fine particles have an average particle size on the order of nanometers ranging from about 1 nm to 100 nm.

The cuprous oxide fine particles according to the invention have a particle size of 1 to 100 nm and satisfy 0.5 Dp≦Dc≦0.8 Dp where the particle size is denoted by Dp and the crystallite diameter is denoted by Dc. In this case, the particle size Dp is an average particle size measured using the BET method and the crystallite diameter Dc is an average crystallite diameter determined by X-ray diffractometry.

It should be noted that the number of cyclones used in the method of producing cuprous oxide fine particles according to the invention is not limited to one but may be two or more.

Fine particles just after the production collide with each other to form agglomerates thereby causing unevenness in particle size, which may reduce the quality. However, dilution of the primary fine particles 15 with cooling gas supplied in the direction of the arrow Q toward the tail portion (end portion) of the thermal plasma flame prevents the fine particles from colliding with each other to agglomerate together.

On the other hand, the cooling gas supplied in the direction of the arrow R along the inner wall of the chamber 16 prevents the primary fine particles 15 from adhering to the inner wall of the chamber 16 in the process of collecting the primary fine particles 15, whereby the yield of the produced primary fine particles 15 is improved.

Under these circumstances, the cooling gas needs to be supplied in an amount sufficient to quench the resulting cuprous oxide fine particles in the process of producing the primary fine particles 15 (cuprous oxide fine particles) and is preferably supplied in such an amount that the flow rate enabling classification of the primary fine particles 15 at any classification point in the downstream cyclone 19 is obtained and that stabilization of the thermal plasma flame 24 is not hindered. The supply method, supply position and the like of the cooling gas are not particularly limited as long as the stabilization of the thermal plasma flame 24 is not hindered. According to the fine particle production apparatus 10 in the embodiment under consideration, a circumferential slit is formed in a top plate 17 to supply the cooling gas but any other method or position may be applied as long as the method or position applied enables reliable supply of gas on the path from the thermal plasma flame 24 to the cyclone 19.

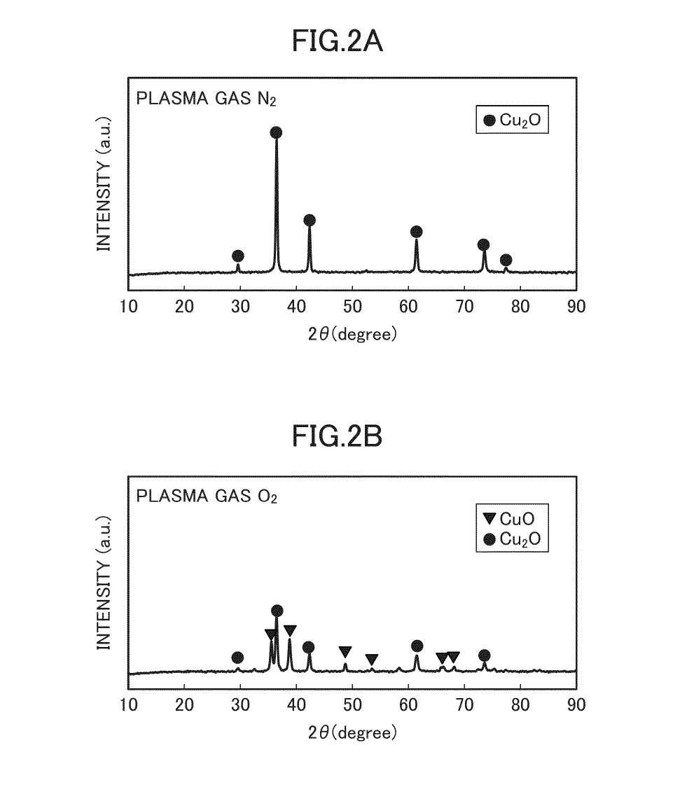

The inventors of the invention confirm that a cuprous oxide (Cu₂O) single phase is obtained as shown in FIG. 2A by supplying the copper compound powder to the thermal plasma flame using nitrogen gas as the plasma gas. On the other hand, in a case where oxygen gas was used as the plasma gas, a multiphase of cupric oxide (CuO) and cuprous oxide (Cu₂O) was obtained as shown in FIG. 2B.

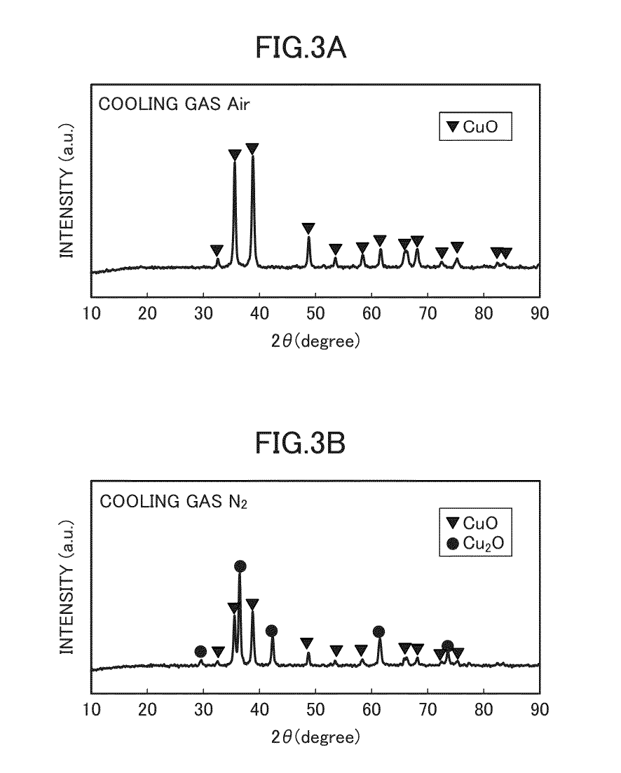

It is confirmed that, in the case where oxygen gas is used as the plasma gas, even if air or nitrogen gas is used as the cooling gas, a cupric oxide (CuO) single phase is obtained as shown in FIG. 3A or a multiphase of cupric oxide (CuO) and cuprous oxide (Cu₂O) is obtained as shown in FIG. 3B, and thus a cuprous oxide (Cu₂O) single phase cannot be obtained.

In addition, the inventors of the invention have made a thorough experimental study and as a result found that cuprous oxide fine particles can be produced without cooling gas in the production of cuprous oxide using copper compound powder.

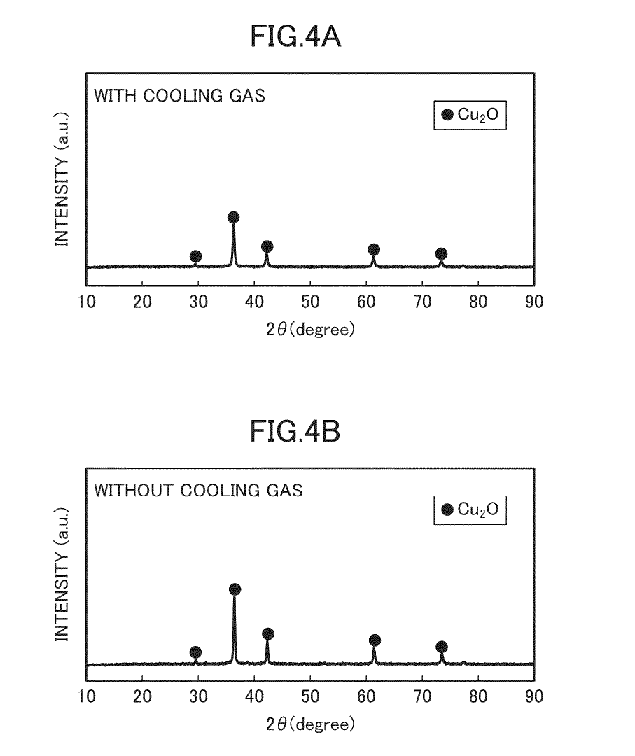

In such a case, according to the analysis of the produced fine particles using X-ray diffractometry, a cuprous oxide (Cu₂O) single phase is obtained in each case as shown in FIGS. 4A and 4B. The average crystallite diameter obtained by X-ray diffractometry was 31 nm in FIG. 4A and 26 nm in FIG. 4B.

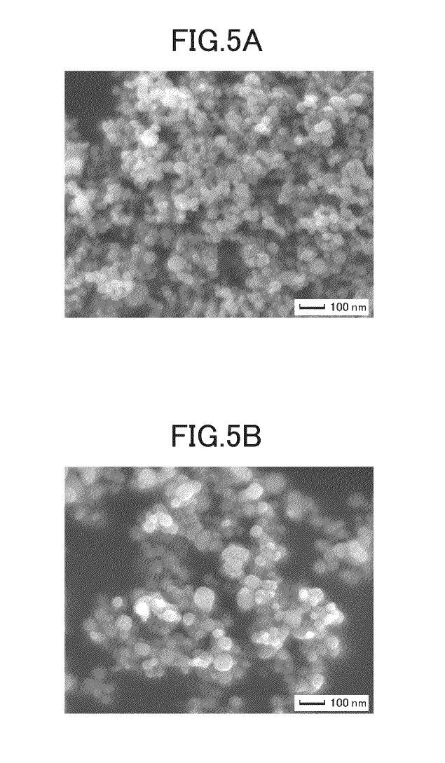

Cuprous oxide fine particles (Cu₂O fine particles) having X-ray diffraction peaks in FIGS. 4A and 4B were as shown in FIGS. 5A and 5B, respectively. FIGS. 5A and 5B correspond to FIGS. 4A and 4B, respectively. The average particle size was 51 nm in FIGS. 4A and 5A and 36 nm in FIGS. 4B and 5B. The average particle size was measured using the BET method.

The ratio of the average crystallite diameter (corresponding to Dc) to the average particle size (corresponding to Dp) (corresponding to Dc/Dp) was 0.61 in FIG. 4A (FIG. 5A) and 0.72 in FIG. 4B (FIG. 5B).

As described above, cuprous oxide fine particles on the order of nanometers can be produced without cooling gas. Accordingly, it is not necessarily indispensable to cool the fine particles with cooling gas and to provide the above-described gas supply device 28.

Next, the case of supply in the form of slurry is described.

In this case, use is made of, for example, powder of a copper compound having an average particle size of up to 5 μm and, for example, water as the dispersion medium. The mixing ratio between the copper compound powder and water is adjusted to 5:5 (50%:50%) in terms of weight ratio to prepare a slurry.

The slurry is introduced into the vessel (not shown) of the material supply device 14 shown in FIG. 1 and agitated by the agitator (not shown). The copper compound powder in water is thus prevented from precipitating, whereby the slurry containing the copper compound powder dispersed in water is maintained. The slurry may be continuously prepared by supplying the copper compound powder and water to the material supply device 14.

Next, the above-described two-fluid nozzle mechanism (not shown) is used to convert the slurry into droplets and the slurry in the form of droplets is supplied into the thermal plasma flame 24 generated in the plasma torch 12 using atomization gas at a predetermined flow rate. Then, the copper compound is reduced to produce cuprous oxide.

At that time, the cuprous oxide fine particles are quenched by nitrogen gas supplied in the direction of the arrow Q and thus quenched in the chamber 16, whereby the production of cupric oxide is also suppressed to obtain primary fine particles 15.

The ambient pressure inside the plasma torch 12 is preferably 1 atm or less. The ambient pressure of 1 atm or less is not particularly limited and is, for example, in a range of 660 Pa to 100 kPa.

In the embodiment under consideration, the amount of the nitrogen gas supplied in the direction of the arrow Q is preferably an amount sufficient to quench the cuprous oxide fine particles in the process of producing the primary fine particles 15. The amount of the nitrogen gas supplied is more preferably such an amount that the flow rate enabling classification of the primary fine particles 15 at any classification point in the downstream cyclone 19 is obtained and that stabilization of the thermal plasma flame is not hindered.

The total amount of the nitrogen gas supplied in the direction of the arrow Q and the nitrogen gas supplied in the direction of the arrow R should be set to 200 vol % to 5,000 vol % of gas supplied into the thermal plasma flame. The gas supplied into the thermal plasma flame as mentioned above refers to the whole of plasma gas for forming the thermal plasma flame, central gas for forming a plasma flow and atomization gas.

The cuprous oxide primary fine particles 15 finally produced in the chamber 16 are subjected to the same process as those prepared in the form of powder as described above.

Similarly to the above-described fine particles prepared in the form of powder, under the negative pressure (suction force) from the collecting section 20, the discharged secondary fine particles (cuprous oxide fine particles) 18 are attracted in the direction indicated by the arrow U and delivered to the collecting section 20 through the inner tube 19e to be collected on the filter 20b of the collecting section 20. The internal pressure of the cyclone 19 at that time is preferably 1 atm or less. An arbitrary particle size on the order of nanometers is defined according to the intended purpose for the particle size of the secondary fine particles (cuprous oxide fine particles) 18.

Also in the form of slurry, the cuprous oxide fine particles on the order of nanometers can be obtained easily and reliably as in the form of powder by merely subjecting the copper compound powder to plasma treatment. Also in this case, the cuprous oxide fine particles can be easily reduced upon thermal treatment in a reducing atmosphere, thereby obtaining copper powder having electrical conductivity. Accordingly, the cuprous oxide fine particles can be used not only in the unreduced form but also as copper.

As shown below, the inventors of the invention check whether or not the resulting cuprous oxide fine particles can be reduced by thermal treatment in a reducing atmosphere.

As mentioned above, the copper compound powder and the thermal plasma flame were used to prepare Sample Nos. 2 to 4 each having a crystal phase and a particle size shown in Table 1. Powder of a single phase of cupric oxide which is a stable copper oxide was prepared for comparison (see “CuO single phase” in Sample No. 1 of Table 1 below).

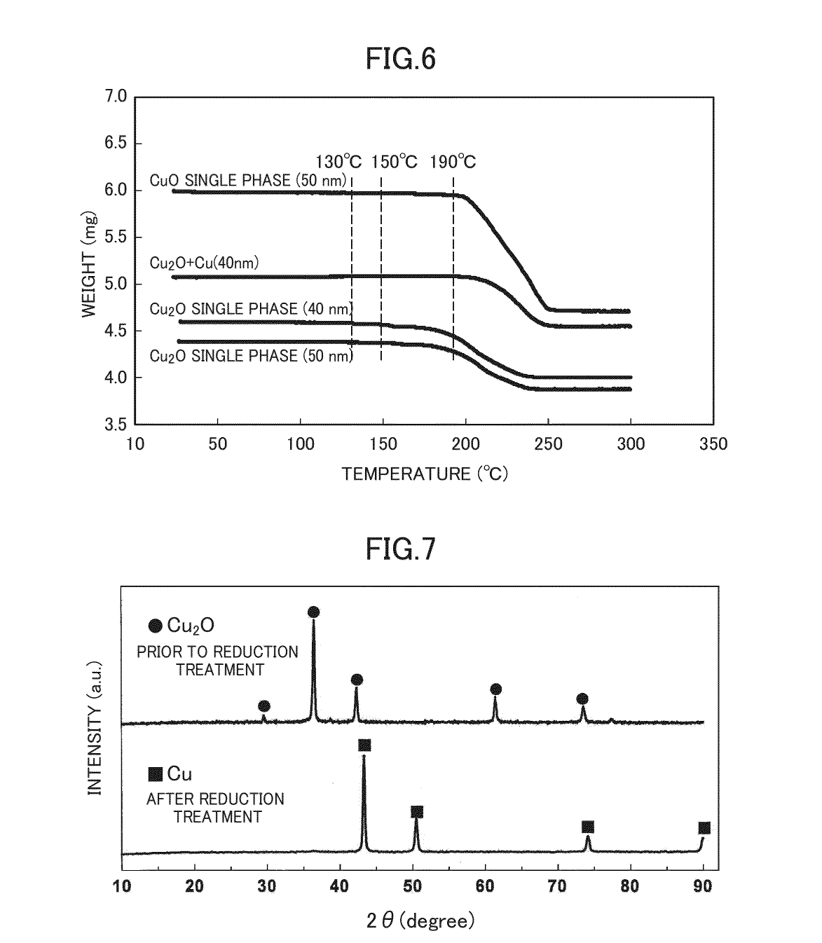

A differential thermal analyzer (TG-DTA) was used to measure the weight variations in each of samples in Sample Nos. 1 to 4 upon heating from room temperature to 300° C. at a temperature elevation rate of 5° C./min in an atmosphere of N:H₂=96:4 vol %, and the weight reduction rate (weight %) was measured. The measurement results of the weight variations upon heating from room temperature to 300° C. are shown in FIG. 6.

The crystal phase was measured using X-ray diffractometry and the particle size is an average particle size measured using the BET method.

The reduction onset temperature shown in Table 1 refers to the lowest temperature at which a weight reduction was confirmed.

When cuprous oxide is reduced, Cu₂O+H₂→2Cu+H₂O proceeds and the calculated value of the weight reduction rate is 11.2 wt %.

When cupric oxide is reduced, CuO+H₂→Cu+H₂O proceeds and the calculated value of the weight reduction rate is 20.1 wt %.

TABLE 1

| | | | Reduction | Weight |
|---|---|---|---|---|
| Sample | | Particle | onset temper- | reduction |
| No. | Crystal phase | size (nm) | ature (° C.) | rate (wt %) |
| 1 | CuO single phase | 50 | 190 | 21.6 |
| 2 | Cu₂O + Cu | 40 | 190 | 10.5 |
| | (small amount) | | | |
| 3 | Cu₂O single phase | 40 | 130 | 13.0 |
| 4 | Cu₂O single phase | 50 | 150 | 11.8 |

As shown in Sample Nos. 2 to 4 in Table 1 above, a value close to the calculated value is obtained for the weight reduction rate in every sample related to Cu₂O, and copper (Cu) having electrical conductivity is obtained by subjecting the cuprous oxide fine particles obtained in the invention to thermal treatment in a reducing atmosphere. In the Cu₂O single phase, the smaller the particle size is, the lower the reduction onset temperature is.

A value close to the calculated value is also obtained in Sample No. 1 for comparison by subjecting the cupric oxide fine particles to thermal treatment in a reducing atmosphere and copper (Cu) having electrical conductivity is obtained.

Whether or not copper was obtained by reduction was checked by measuring the weight reduction rate (wt %) in the above-described Sample Nos. 1 to 4 but in addition to this, whether or not copper was obtained by reduction was checked by performing thermal treatment in a reducing atmosphere. In this case, cuprous oxide fine particles in the same sample as Sample No. 4 were used and heated at a temperature of 200° C. for 2 hours in an atmosphere of N:H₂=96:4 vol % which is the same as that applied in the measurement of the weight reduction rate (wt %) in the above-described Sample Nos. 1 to 4.

FIG. 7 shows analysis results of cuprous oxide fine particles in Sample No. 4 prior to heating according to X-ray diffractometry, and analysis results of cuprous oxide fine particles in Sample No. 4 having undergone thermal treatment according to X-ray diffractometry. This reveals that the whole of Cu₂O was reduced to Cu because there was no peak of Cu and Cu₂O accounted for the total amount prior to thermal treatment, whereas Cu accounted for the total amount and there was no peak of Cu₂O after thermal treatment.

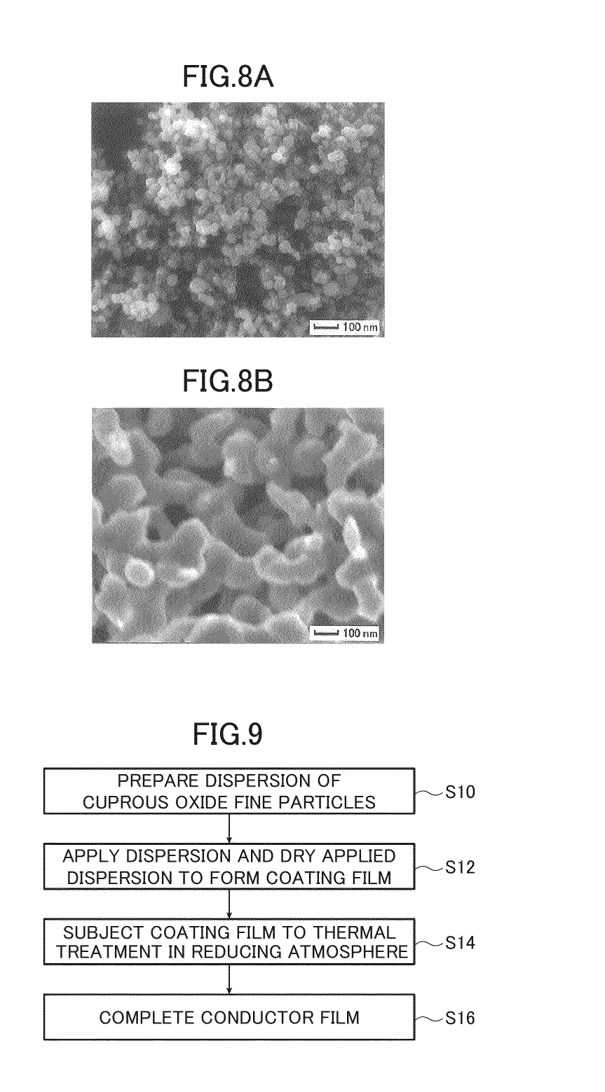

FIG. 8A is a micrograph substituted for a drawing showing the particles in Sample No. 4 prior to thermal treatment; and FIG. 8B is a micrograph substituted for a drawing showing the particles in Sample No. 4 after thermal treatment is performed at a temperature of 200° C. for 2 hours.

FIG. 8A shows cuprous oxide fine particles in No. 4 prior to thermal treatment and it is seen that the particles are separated into primary particles. Then, the average particle size according to the BET method was 50 nm. FIG. 8B shows cuprous oxide fine particles in No. 4 after thermal treatment and it is seen that the particles are fused together to form larger particles. Then, the average particle size according to the BET method was 150 nm.

Since fusion occurs after thermal treatment as shown in FIG. 8B, the electric resistance at the particle interface between particles is deemed to be sufficiently small.

The cuprous oxide fine particles according to the invention can be used in, for example, preservatives for use in ship bottom paints (antifouling paints), germicides, pesticides, catalysts, rectifiers, and colorants in the ceramic field.

The cuprous oxide fine particles according to the invention may also be used in various devices such as solar cells and light-emitting devices.

The cuprous oxide fine particles according to the invention can be reduced to copper and be used in, for example, wiring of printed circuit boards including flexible boards, wiring of touch panels, and flexible electronic paper.

It is also possible to obtain a copper conductor film according to the procedure described below by using a dispersion containing the cuprous oxide fine particles of the invention dispersed in an organic solvent or the like. The conductor film can be used in, for example, wiring of printed circuit boards, wiring of touch panels, and flexible electronic paper as described above.

FIG. 9 is a flow chart illustrating a method of producing a conductor film using the cuprous oxide fine particles according to the invention.

For the above-described conductor film, a dispersion containing the cuprous oxide fine particles of the invention dispersed in an organic solvent or the like is prepared (Step S10). Next, the foregoing dispersion obtained by dispersing in an organic solvent or the like is applied onto a resin film or a substrate such as a glass substrate or a ceramic substrate and is then dried to obtain a coating film (Step S12). Then, the coating film is heated for reduction in a reducing atmosphere at a predetermined temperature for a predetermined period of time (Step S14) to obtain a copper conductor film (Step S16). The copper conductor film can be thus reliably produced with the use of the cuprous oxide fine particles according to the invention.

In order to improve the electrical conductivity, reduction treatment (Step S14) may be followed by heating to a predetermined temperature for oxidation and subsequently by the above-described reduction treatment. The above-described oxidation treatment and reduction treatment may be repeated a predetermined number of times.

The above-described conductor film is formed, for example, in a wiring pattern shape. The conductor film is used in at least one of at least a printed circuit board, a touch panel and a flexible board. In addition, the above-described conductor film may also be used in an internal electrode or an external electrode of an electronic component such as an MLCC (multilayer ceramic capacitor).

The cuprous oxide fine particles according to the invention may be further used as a material of copper powder for electronic materials. In this case, the cuprous oxide fine particles may be used in, for example, a conductive paste, a conductive coating material and a copper plating solution. For example, copper powder obtained by reducing the cuprous oxide fine particles is used in a conductive paste. The conductive paste is used to form an internal electrode, an external electrode and the like in a multilayer ceramic electronic component such as a multilayer ceramic capacitor or a multilayer ceramic inductor. In addition to this, the conductive paste using copper powder obtained by reducing the cuprous oxide fine particles of the invention may be utilized to form a conductor film, wiring and the like.

The present invention is basically as configured above. While the method of producing cuprous oxide fine particles and the cuprous oxide fine particles as well as the method of producing a conductor film according to the invention have been described above in detail, the invention is by no means limited to the foregoing embodiments and it should be understood that various improvements and modifications are possible without departing from the scope and spirit of the invention.

### DESCRIPTION OF SYMBOLS

10 Fine particle production apparatus

12 Plasma torch

14 Material supply device

15 Primary fine particles

16 Chamber

18 Fine particles (secondary fine particles)

19 Cyclone

20 Collecting section

22 Plasma gas supply source

24 Thermal plasma flame

28 Gas supply device

1. A cuprous oxide fine particle production method comprising:
a production step of producing cuprous oxide fine particles using copper compound powder and a thermal plasma flame,
wherein the thermal plasma flame is derived from an inert gas.

2. The cuprous oxide fine particle production method according to claim 1, wherein the production step comprises a step of dispersing the copper compound powder using a carrier gas to supply the copper compound powder into the thermal plasma flame.

3. The cuprous oxide fine particle production method according to claim 1, wherein the production step comprises:
a step of dispersing the copper compound powder in water to obtain a slurry; and
a step of converting the slurry into droplets to supply the droplets into the thermal plasma flame.

4. The cuprous oxide fine particle production method according to claim 1, wherein the copper compound powder is cupric oxide powder.

5. The cuprous oxide fine particle production method according to claim 1, wherein the production step further comprises a step of supplying a cooling gas to an end portion of the thermal plasma flame.

6. The cuprous oxide fine particle production method according to claim 1, wherein the inert gas is at least one selected from helium gas, argon gas and nitrogen gas.

7. Cuprous oxide fine particles having a particle size of 1 to 100 nm and satisfying 0.5 Dp≦Dc≦0.8 Dp where the particle size is denoted by Dp and a crystallite diameter is denoted by Dc.

8. A conductor film production method comprising:
a step of dispersing cuprous oxide fine particles having a particle size of 1 to 100 nm and satisfying 0.5 Dp≦Dc≦0.8 Dp where the particle size is denoted by Dp and a crystallite diameter is denoted by Dc in a solvent to obtain a dispersion;
a step of applying the dispersion onto a substrate and drying the applied dispersion to form a coating film; and
a step of heating the coating film in a reducing atmosphere for a predetermined period of time to obtain a conductor film.

9. The conductor film production method according to claim 8, wherein the conductor film is formed in a wiring pattern shape.

10. The conductor film production method according to claim 8, wherein the conductor film is used in at least one of at least a printed circuit board, a touch panel and a flexible board.

11. The conductor film production method according to claim 8, wherein the conductor film is used in an internal electrode or an external electrode of an electronic component.

12. The cuprous oxide fine particle production method according to claim 2, wherein the copper compound powder is cupric oxide powder.

13. The cuprous oxide fine particle production method according to claim 3, wherein the copper compound powder is cupric oxide powder.
